(19) United States
(12) Patent Application Publication
(10) Pub. No.: US 2009/0045803 A1
(43) Pub. Date: Feb. 19, 2009

(54) System and Method for Premises Power Parameter and Power-Factor Reporting and Management

(75) Inventor: Roland Schoettle, Freeport GBI (BS)

Correspondence Address: FULBRIGHT & JAWORSKI L.L.P, 2200 ROSS AVENUE, SUITE 2800, DALLAS, TX, 75201-2784, US

(73) Assignee: Optimal Innovations Inc., Bridgetown (BB)

(21) Appl. No.: 12/168,775

(22) Filed: Jul. 7, 2008

Related U.S. Application Data
(60) Provisional application No. 60/955,920, filed on Aug. 15, 2007.

(51) Int. Cl. G01R 19/06; H02J 3/18

(52) U.S. Cl. 324/140 D; 700/295; 340/658

(57) ABSTRACT

System and methods in which endpoint control devices, such as, for example, switches and wall sockets, are arranged to monitor the power used by the controlled load as well as the power-factor of the load. In one embodiment, the monitored power and power-factor of a controlled device is fed back to a central point within the premises and then sent on to a more global monitoring point. In one embodiment, the endpoint device can send power parameter data to another location and receive instructions as to maximum allowable loads for a given power parameter or power-factor.

### CROSS-REFERENCE TO RELATED APPLICATIONS

This application claims priority from U.S. Provisional Patent Application No. 60/955,920, entitled “SYSTEMS AND METHODS FOR PREMISES POWER PARAMETER AND POWER-FACTOR REPORTING AND MANAGEMENT” and filed Aug. 15, 2007, the disclosure of which is hereby incorporated herein by reference.

### TECHNICAL FIELD

This disclosure relates to premises electrical systems and more specifically to systems and methods for premises power, power factor, load factor, power quality reporting and measurement and verification-based load modeling, and even more particularly to endpoint control devices that provide premises power and power-factor reporting control.

### BACKGROUND OF THE INVENTION

Many systems exist today that provide power and power-factor reporting for a given premises. For example, reference is made to U.S. Pat. No. 7,089,089, U.S. Pat. No. 7,145,439, and U.S. Pat. No. 6,418,419.

For the purpose of this discussion, “Load Profiles” can include time stamped static and dynamic parameters of real power, reactive power, power factor, frequency, impedance, current, voltage, phasor and phase data, load factor, load diversity, power quality, power sags, power dips, power swells, load limits, flicker, transients, harmonics, interruptions, unbalances, noise, linearity, sensitivity, variability (e.g., for weather, seasons, geography, load factor, contribution) and other less common parameters.

Electrical power consumption measurement and distribution is a complex undertaking and must, if done properly take into account accurate load parameters. From a grid perspective, assessing these parameters correctly can have a dramatic effect on the safety margins required to maintain stable system operation and is a critical issue for grid operations and planning. This is typically performed using various computerized methodologies typically called computer load models that all too often differ in their output and that cannot be verified with real-world measurement at the load itself because of cost and custom installation requirements of the measurement devices themselves. Further, it should be noted that the prevailing meters now installed on premises and the vast majority of new “advanced meter initiative” meters cannot provide the necessary data for accurate load profiles further exacerbating the ability to generate accurate or even reasonable load models. In fact, the simple data now collected can easily hide an impending catastrophic problem. Grid operators and planners must therefore include significant reserve capacity margins to cover hidden problems. These inflated margins typically are described in terms of reduced reliability, increased grid system congestion, and extra generation, transmission, and distribution costs to avoid unreliable operation. The requirement for added reserve margins in turn produces additional negative environmental impacts. Grid-side environmental impacts due to inflated margins are usually further compounded by a factor of three (3) because it typically requires three units of prime energy (e.g., coal, natural gas, diesel fuel, etc.) to produce one unit of electricity (utility-scale generators are typically 30-35% efficient). Having accurate load/power behavior data for normal and abnormal grid and load conditions is therefore critical for significant improvements to power system operation and reduced environmental impact.

Inaccurate or missing load data parameters are also problematic for the end-user. For example: in many markets, commercial electricity users must pay for electricity based on the highest “15 minute” peak consumption—meaning the highest 15 minute interval in any billing period sets the electricity price for the entire billing period (e.g., monthly). To solve the challenge of reducing peak consumption, it is highly beneficial to have each premises' electric infrastructure report its real-world measurement and verification for both utility and end-user purposes. One way to accomplish this is to include load profile circuitry in each light bulb that typically would require recalibration in relation to other devices each time a new bulb is installed. This is not practical for a variety of reasons, such as cost. Further, if the load profiling circuitry were to be in each bulb, it is highly likely that certain critical time based information would be lost when the failed old bulb is discarded as useful data would likely be discarded with the dead bulb.

Although any of the Load Model parameters described above can cause severe power delivery challenges for the utility and the end-user, for the purpose of illustration we now will focus on one of the more common aspects of load parameter modeling called power factor. As discussed in Wikipedia, the power factor of an AC power system is defined as the ratio of the real power to the apparent power, and is a number between 0 and 1. Real power is the capacity of the circuit for performing work in a particular time. Apparent power is the product of the current and voltage of the circuit. Due to energy stored in the load and returned to the source, or due to a non-linear load that distorts the wave shape of the current drawn from the source, the apparent power is equal to or greater than the real power. Low-power-factor loads increase losses in a power distribution system and result in increased energy costs.

A particularly important example is the millions of personal computers that typically incorporate switched-mode power supplies (SMPS) with rated output power ranging from 150 W to 500 W. Historically, these very low cost power supplies incorporated a simple full wave rectifier that conducted only when the mains instantaneous voltage exceeded the voltage on the input capacitors. This leads to very high ratios of peak to average input current, which also lead to a low distortion power factor and potentially serious phase and neutral loading concerns.

Another important aspect of load modeling is load factor contribution. For example: there are many buildings that are often over air-conditioned for many regions so as to provide sufficient cooling for certain other regions (e.g., computer rooms). This leads to many people within the cold areas of the building adding plug-in heaters to heat their legs, cubicles, or rooms. In fact, in a study performed in Silicon Valley, Calif., the load added from small plug-in heaters was found to be higher than the load required to operate the HVAC systems. A proper load model determined from accurate load parameters would allow these conflicting operations to be seen easily and to indicate remedies.

Thus, when this data is collected for a given area it forms a basis for decisions on future power requirements and consumption and is especially important when decisions must be made for a) grid and environmental conditions, usually on an emergency basis, as to load shedding in view of a pending (or actual) power outage or reduction in availability; and, b) end-user peak reductions for billing cycle cost optimization.

However, for grid concerns, simply knowing an area's power consumption and power-factor is not enough when trying to plan for additional long term power for that area and it certainly does not allow for emergent conditions when loads must be shed in order to maintain an orderly power availability to the area. The same is also true for end-user concerns, where energy efficiency, including increased power factor and peak reductions must be met to achieve cost and emissions objectives. For example, it does no good simply to know that a certain area has an inductive load without being able to know precisely where that load is, the times when it is on line, load type, and how many other local loads and load types can be managed within the area. Ability to selectively and intelligently isolate particular loads based on load model data is also important. Proper utility and end-use planning then requires more precise knowledge of what loads are available and where those loads are in the power grid and in the premise.

### BRIEF SUMMARY OF THE INVENTION

The present invention is directed to a system and method in which endpoint control devices, such as, for example, switches and wall sockets, are arranged to monitor load model parameters of the controlled load. In one embodiment, the monitored power and power-factor of a controlled device is fed back to a central point within the premises and then sent on to a more global monitoring point. In one embodiment, the endpoint device can, from time to time, receive instructions as to maximum allowable loads for a given power-factor and a given region. In another embodiment, the endpoint device can perform dynamic and steady-state load modeling and manage and send and receive instructions based on normal and anomaly conditions.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims. The novel features which are believed to be characteristic of the invention, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present invention.

### BRIEF DESCRIPTION OF THE DRAWINGS

For a more complete understanding of the present invention, reference is now made to the following descriptions taken in conjunction with the accompanying drawing, in which:

FIG. 1 shows one embodiment of a premises having end-point power monitoring;

FIGS. 2 and 3 show embodiments of end-point control devices operable for power parameter monitoring;

FIG. 4 shows one embodiment of a premises monitoring control for coordinating power parameter measurements and control from a number of devices; and

FIG. 5 shows one embodiment of a system for area monitoring and control of power parameters.

### DETAILED DESCRIPTION OF THE INVENTION

Note that the discussion below is centered around power factor and power parameter monitoring and control at end-point devices. The term power-factor, while only being one sub-set of power modeling, is used herein as an example only to include any and all aspects of power measurements. Any and all aspects of power consumption, supply and management can be handled using the concepts discussed herein with respect to any and all load profiles.

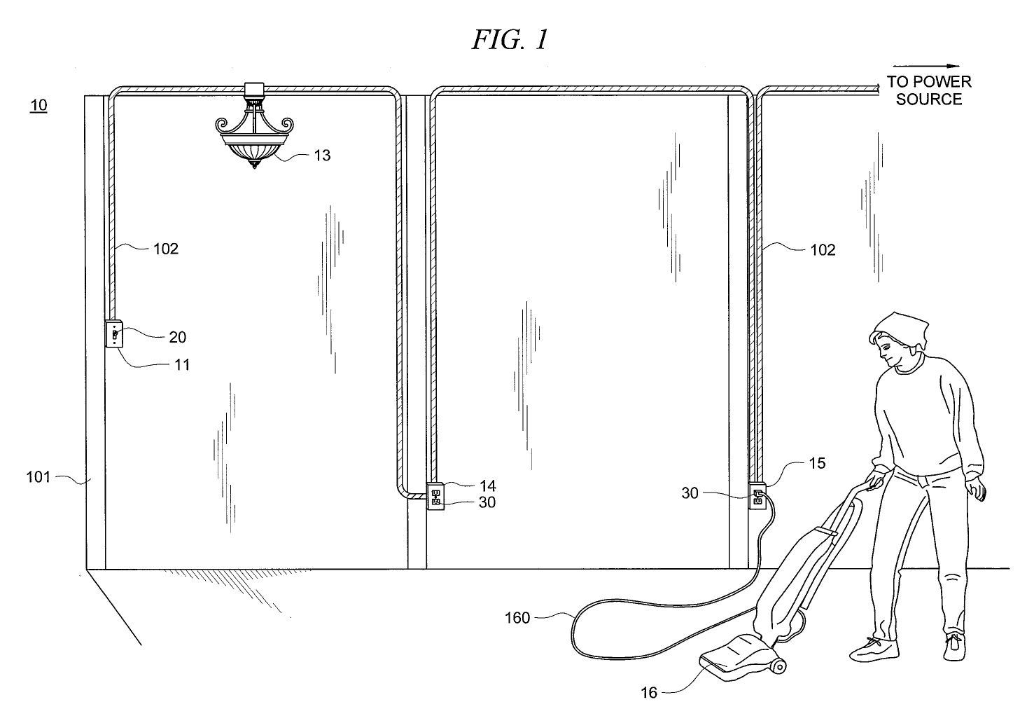

FIG. 1 shows one embodiment 10 of a premises having end-point power parameter monitoring. Premises electrical wiring 102 is shown, in one embodiment, attached to studding or other framework of the premises. The premises can be a home, office, apartment, industrial building or complex in which a number of locations, such as locations 11, 14 and 15 have electrical control devices, such as devices 20 and 30, positioned thereat. In the embodiment shown, locations 11, 14 and 15 are electrical utility boxes permanently mounted to the premises structure and the electrical control device are positioned within the utility boxes.

Control device 20 is a light switch controlling light 13 while device 30 is an electrical wall socket into which sweeper 16 is plugged via power cord 160. Of course, any number of different devices can be controlled by either switch 20 or socket 30. In the situation with switch 20, the load is constant, either on or off while with socket 30 its load can vary from time to time depending upon what is plugged into it at the time. However some sockets have a relatively permanent assignment, such as, for example, when a washer or refrigerator, ice maker, etc, is plugged into the socket. Also, some equipment is hand-wired into the junction box and thus the control device serving such equipment would not have a plug or switch on its outside.

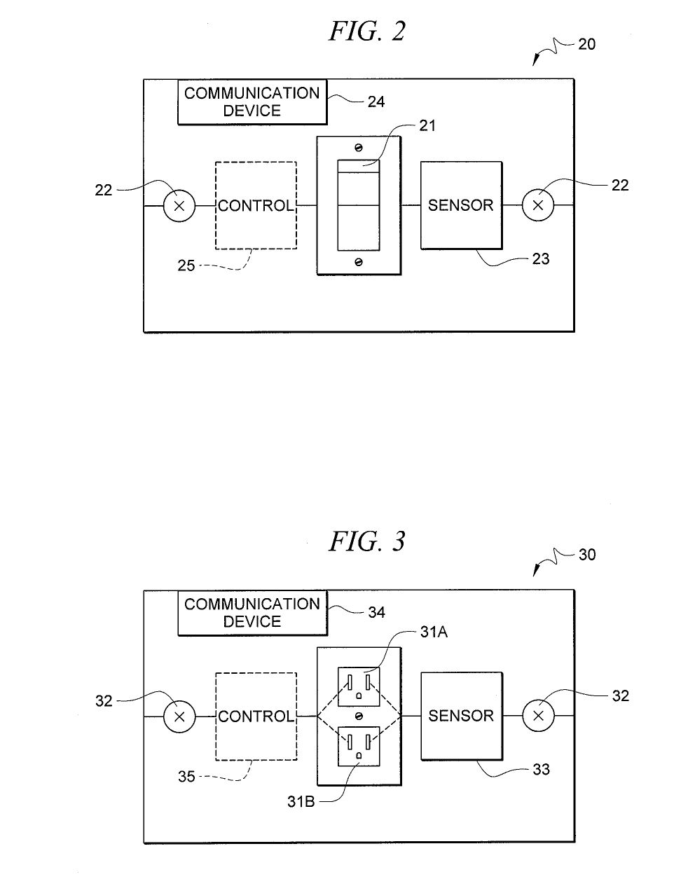

FIG. 2 shows one embodiments of switch 20 acting as an end-point control device for power parameter monitoring. Switch 20 is shown containing a typical on-off switch 21 which normally would be connected to wiring 102 (FIG. 1) via terminals 22. In the embodiment shown, sensor 23 is connected in series between one terminal 22 and the switch. Note this connection can be a series connection or the sensor, in some embodiments can be across terminals 22 if desired or both. The purpose of sensor 23 is to measure power parameters such as power flow in the circuit as well as power-factor. In the case of an incandescent light circuit, the load would be purely resistive and thus the power-factor would be 1.

In a purely resistive AC circuit, voltage and current waveforms are in step (or in phase), changing polarity at the same instant in each cycle. Where reactive loads are present, such as with capacitors or inductors, energy storage in the loads result in a time difference between the current and voltage waveforms. This stored energy returns to the source and is not available to do work at the load. A circuit with a low power factor will have thus higher currents to transfer at a given quantity of power than a circuit with a high power factor.

Circuits containing purely resistive heating elements (filament lamps, strip heaters, cooking stoves, etc.) have a power factor of 1.0. Circuits containing inductive or capacitive elements (lamp ballasts, motors, etc.) often have a power factor below 1.0. For example, in electric lighting circuits, normal power factor ballasts (NPF) typically have a value of (0.4)-(0.6). Ballasts with a power factor greater than (0.9) are considered high power factor ballasts (HPF).

The significance of power factor lies in the fact that utility companies supply customers with volt-amperes, but bill them for watts. Power factors below 1.0 require a utility to generate more than the minimum volt-amperes necessary to supply the real power (watts). This increases generation and transmission costs. Good power factor is considered to be greater than 0.85 or 85%. Utilities may charge additional costs to customers who have a power factor below some limit.

AC power flow has the three components: real power (P), measured in watts (W); apparent power (S), measured in volt-amperes (VA); and reactive power (Q), measured in reactive volt-amperes (VAr).

The power factor is defined as:

$$\frac{P}{S} .$$

In the case of a perfectly sinusoidal waveform, P, Q and S can be expressed as vectors that form a vector triangle such that:

S²=P²+Q².

If φ is the phase angle between the current and voltage, then the power factor is equal to |cos φ|, and:

P=S|cos φ|.

By definition, the power factor is a dimensionless number between 0 and 1. When power factor is equal to 0, the energy flow is entirely reactive, and stored energy in the load returns to the source on each cycle. When the power factor is 1, all the energy supplied by the source is consumed by the load. Power factors are usually stated as “leading” or “lagging” to show the sign of the phase angle.

If a purely resistive load is connected to a power supply, current and voltage will change polarity in step, the power factor will be unity (1), and the electrical energy flows in a single direction across the network in each cycle. Inductive loads such as transformers and motors (any type of wound coil) generate reactive power with current waveform lagging the voltage. Capacitive loads such as capacitor banks or buried cable generate reactive power with current phase leading the voltage. Both types of loads will absorb energy during part of the AC cycle, which is stored in the device's magnetic or electric field, only to return this energy back to the source during the rest of the cycle.

For example, to obtain 1 kW of real power if the power factor is unity, 1 kVA of apparent power needs to be transferred (1 kW÷1=1 kVA). At low values of power factor, more apparent power needs to be transferred to get the same real power. To get 1 kW of real power at 0.2 power factor 5 kVA of apparent power needs to be transferred (1 kW÷0.2=5 kVA).

It is often possible to adjust the power factor of a system to very near unity. This practice is known as power factor correction and is achieved by switching in or out banks of inductors or capacitors. For example the inductive effect of motor loads may be offset by locally connected capacitors.

Energy losses in transmission lines increase with increasing current. Where a load has a power factor lower than 1, more current is required to deliver the same amount of useful energy. Power companies therefore require that industrial and commercial customers maintain the power factors of their respective loads within specified limits or be subject to additional charges. Engineers are often interested in the power factor of a load as one of the factors that affect the efficiency of power transmission.

In circuits having only sinusoidal currents and voltages, the power factor effect arises only from the difference in phase between the current and voltage. This is narrowly known as “displacement power factor”. The concept can be generalized to a total, distortion, or true power factor where the apparent power includes all harmonic components. This is of importance in practical power systems which contain non-linear loads such as rectifiers, some forms of electric lighting, electric arc furnaces, welding equipment, switched-mode power supplies and other devices.

Sensor 23, which could be a RMS multimeter, measures the actual RMS currents and voltages and therefore measures the apparent power. To measure the real power or reactive power, a wattmeter designed to properly work with non-sinusoidal currents is used.

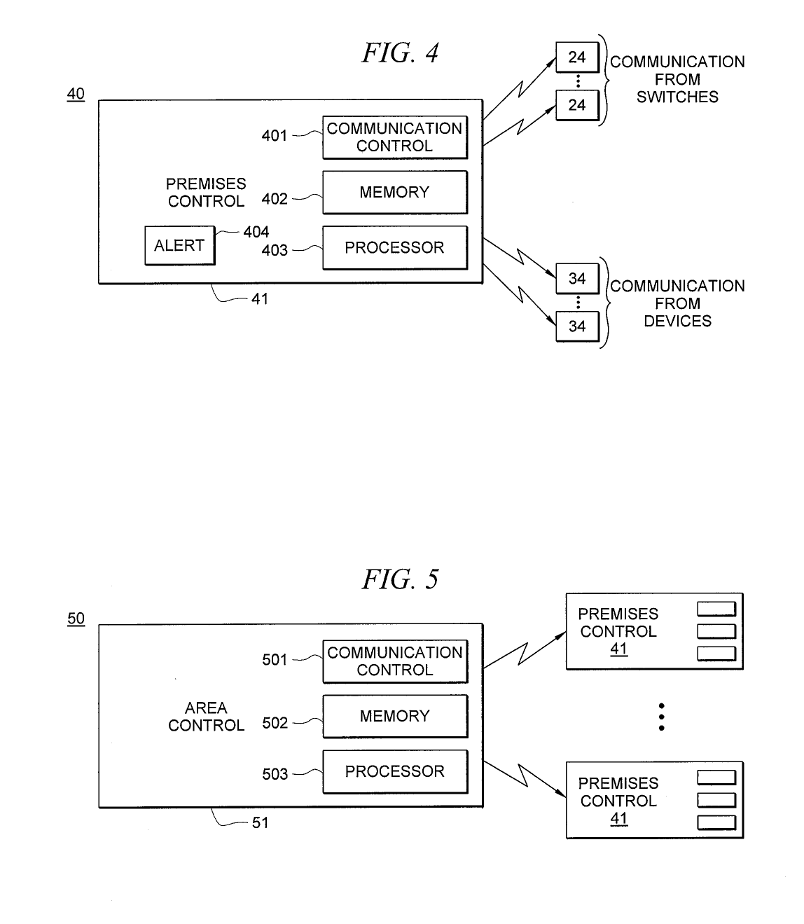

Communications device 24 sends the collected data to a location external to the device via signals transmitted over the electrical wire, or via RF or a combination thereof. One such location will be discussed with respect to FIG. 4.

Optional control device 25 operates to receive instruction (or to have instructions pre-programmed therein such that device 20 will operate to maintain its load within a set of limits which limits could include power factor limits. These limits could be set from time to time under instructions communicated thereto from an external source. Note that the control instructions to the load could also come from control circuitry in a common device, such as from control 401, FIG. 4, or control 501, FIG. 5.

Using a control device, such as device 20, load modeling functions can be performed at the building infrastructure endpoint that services the load and not within the load itself. When done at the building infrastructure endpoint, load profiles can be calibrated at installation for the life of the building without regard to the life of the endpoint device. This then avoids the problems of recalibration in relation to other devices each time a new device (bulb, etc.) is installed as compared to load modeling for the lighting circuit. This approach also benefits from the easy replacement of more efficient devices (e.g., changing light bulb technology from incandescent to compact fluorescent) without having to recalibrate each new device into the system because the lighting circuit would maintain its previous calibration. This approach becomes incrementally more beneficial as heavy energy consuming devices improve in technology. For example, technological advances in large air conditioning units would provide greater end-user and grid benefits when load modeled over time (trended) due to their high power requirements. Such trending data could then be used, for example, for a) on-demand maintenance to determine when condensers or air filters become plugged due to longer than normal run times; or, b) the precise time when an old device should be replaced with a new device to reduce operating and maintenance costs. More advanced applications could include the ability to determine when two or more units are to start simultaneously and then to sequence their start times so as to reduce instantaneous peaks thereby reducing costs.

FIG. 3 shows one embodiments of wall socket 30 acting as an end-point control device for power monitoring. Socket 30 is shown containing a typical dual wall socket 31A and 31B which normally would be connected to wiring 102 (FIG. 1) via terminals 32. In the embodiment shown, sensor 33 is connected in series between one terminal 32 and one side of the socket. Note this connection can be a series connection or the sensor, in some embodiments can be across terminals 32 if desired or wired both in series and in parallel. The purpose of sensor 32 is to measure power flow in the load as well as the load's power-factor. Communication device 34 and optional control 35 work as discussed above for elements 24 and 25, respectively of device 20.

FIG. 4 shows one embodiment 40 of premises monitoring control 41 for coordinating power measurements and control from a number of devices, such as from communications control devices 24 and 34 of end-point control devices 20 and 30. In one embodiment, the data received from each such end-point control device is received by communications control 401 and stored in memory 402 under control of processor 403. This stored data then can be organized for review in any manner desired and if desired can be sent on, in batch if desired, to an area wide gathering point, such as will be discussed with respect to FIG. 5. Note that alert 404 can provide visual and low audible alert of an anomaly condition at one or more end-points. Also note that the alert device could, if desired, be positioned in one or more control devices 20.

Control 41 can also send instructions to one or more devices 20 or 30 setting power and/or power factor limits for one or more end-point control devices. Thus, if the power company, or other agency, sends a notice out that power must be reduced by a certain amount, control 41 can use its own premises profile, and the information obtained (either previously stored or newly obtained) to set the limits it deems appropriate for the situation. These limits can be changed from time to time on a premises by premises basis as established, perhaps, by the premises manager. Each end-point control device can then carry out the instruction for the load it controls. In this manner, not only can the power be controlled but also the power factor can be properly managed.

FIG. 5 shows one embodiment 50 of a system for area monitoring and control of power. Area control 51 monitors, for example, devices 41 at a number of premises via communications control 501 and stores the results, if desired, in memory 502 under control of processor 503. Note that the polling of the various premises devices can be randomly, sequentially or by token setting when new information is available. This monitoring can be by wireline or wireless. In situations were power adjustments are desired across a wide area, control 51 will likely broadcast the desired information to a number, if not all, of the premises within the area of coverage.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A premises control device comprising:
a power monitor operable for monitoring power parameters from loads controlled by said device; and
a control for communicating monitored power parameters to a location external to said device.

2. The device of claim 1 wherein said power monitor is further operable for monitoring a power-factor of said loads and wherein said control communicates monitored power-factors to said external location.

3. The device of claim 2 wherein said device is adapted for permanent mounting in said premises where the primary function of said device is other than either said power parameter monitoring or said power-factor monitoring.

4. The device of claim 2 wherein said device is selected from the list consisting of: wall mounted electrical switch, wall mounted electrical socket, permanently installed electrical box, junction box, electrical panel.

5. The device of claim 2 wherein said communicating is selected from the list of: signals sent over premises wiring; wireless signals from said device to a central control location.

6. The device of claim 2 further comprising:
a control device associated with said premises operable for collecting said power parameter and said power-factor data from a plurality of devices at said premises.

7. The device of claim 6 wherein said control device further comprises:
means for communicating said collected power parameter and said power-factor data to a system located remotely from said premises.

8. The device of claim 2 further comprising:
a control for limiting power parameters to said loads to within a range, said range including a power-factor.

9. The device of claim 8 wherein said control comprises:
at least one visual indication of power parameters and power-factor exceeding a limit.

10. The device of claim 8 wherein said control comprises:
at least one alert indication of power parameters and power-factor exceeding a limit.

11. A method for determining power parameters; including power consumption of a load, said method comprising:
monitoring power parameter levels from loads controllable by a control device; and
communicating said monitored power parameter levels to a location external to said device.

12. The method of claim 11 further comprising:
monitoring a power-factor of said load; and
communicating said monitored power-factors to said external location.

13. The method of claim 12 wherein said control device is mounted permanently to a structure within a premises housing said load.

14. The method of claim 13 wherein said device is selected from the list consisting of: wall mounted electrical switch, wall mounted electrical socket, permanently installed electrical box, junction housing, electrical panel.

15. The method of claim 13 wherein said communicating is selected from the list of: signals sent over said premises permanent wiring; wireless signals to said external location.

16. The method of claim 13 further comprising:
gathering said communicated power parameter levels and said communicated power-factors from a plurality of devices within said premises.

17. The method of claim 16 wherein said gathering comprises:
collecting from each of said plurality of devices summaries of said power parameters and said power-factors at said premises.

18. The method of claim 13 further comprising:
sending said power parameter levels and said power-factors from a plurality of devices within said premises to a location outside said premises.

19. The method of claim 18 further comprising:
sending a plurality of power parameter levels and power-factors from a plurality of premises to said outside location.

20. The method of claim 19 wherein said gathering comprises:
collecting from each of a plurality of premises summaries of said power parameters and said power-factors at each said premises.

21. The method of claim 13 further comprising:
limiting power parameters to said load to within a range, said range including a power-factor.

22. The method of claim 11 wherein said control comprises:
providing at least one alert when a power parameter exceeds a limit.

23. The method of claim 13 wherein said limit is received from time to time from a source external to said premises.

24. A control device for mounting in a premises utility box for controlling electrical power to loads within said premises; said device comprising:
means for supplying power to a load associated with said device; and
means for measuring, on an ongoing basis, power consumed by said associated load.

25. The device of claim 24 wherein said consumed power includes a power-factor.

26. The device of claim 25 further comprising:
means for maintaining said load within a given power parameter.

27. The device of claim 26 wherein said maintaining means comprises:
means for receiving from time to time a value for said given power parameter.

28. The device of claim 26 further comprising:
means for sending a value for said determined power parameter.

29. The device of claim 25 further comprising:
means for receiving from time to time a given power level; and
means for maintaining said load within said given power level.

30. The device of claim 25 further comprising:
means for sending a given power level; and
means for maintaining said load within said sent power level.

31. The device of claim 25 further comprising:
means for communicating measured ones of said power parameters and power-factor to at least one location remote from said device.

32. The device of claim 31 wherein said remote location is external to said premises.
